(19) United States
(12) Patent Application Publication
(10) Pub. No.: US 2025/0212628 A1
(43) Pub. Date: Jun. 26, 2025

(54) DISPLAY SUBSTRATE AND METHOD FOR MANUFACTURING THE SAME, AND DISPLAY DEVICE

(71) Applicant: BOE Technology Group Co., Ltd., Beijing (CN)

(72) Inventors: Zhichong WANG, Beijing (CN); Jing FENG, Beijing (CN)

(73) Assignee: BOE Technology Group Co., Ltd., Beijing (CN)

(21) Appl. No.: 18/850,070

(22) PCT Filed: Nov. 16, 2023
(86) PCT No.: PCT/CN2023/131975

§ 371 Date: Sep. 24, 2024

(30) Foreign Application Priority Data
Dec. 26, 2022 (CN) 202211676067.8

(51) Int. Cl. H10K 59/131; H10K 59/12; H10K 59/121

(52) U.S. Cl. CPC H10K 59/131; H10K 59/1201; H10K 59/1213

(57) ABSTRACT

A display substrate includes pixel driving circuits, a substrate, a first gate conductive layer, a second gate conductive layer and a first source-drain conductive layer. Each pixel driving circuit includes a first transistor and a storage capacitor. The first transistor includes a first gate pattern located in the first gate conductive layer, and the first gate pattern is also used as a first electrode plate of the storage capacitor. The storage capacitor includes a second electrode plate located in the second gate conductive layer. Orthographic projections, on the substrate, of the second electrode plate and the first electrode plate partially overlap. The first source-drain conductive layer includes at least one conductive pattern, and a conductive pattern is electrically connected to the second electrode plate. The conductive pattern includes a sub-portion. Orthographic projections, on the substrate, of the sub-portion and the first electrode plate overlap.

### CROSS-REFERENCE TO RELATED APPLICATIONS

This application is a national phase entry under 35 USC 371 of International Patent Application No. PCT/CN2023/131975, filed on Nov. 16, 2023, which claims priority to Chinese Patent Application No. 202211676067.8, filed on Dec. 26, 2022, each are incorporated herein by reference in their entirety.

### TECHNICAL FIELD

The present disclosure relates to the field of display technologies, and in particular, to a display substrate and a method for manufacturing the same, and a display device.

### BACKGROUND

Organic light-emitting diode (OLED) display technology is a technology that uses luminescent materials to emit light under the drive of electric current to achieve display. OLED displays have the advantages of being ultra-light, ultra-thin, high brightness, wide viewing angle, low voltage, low power consumption, fast response, high definition, shock-resistant, bendable, low cost, simple process, less raw materials used, high luminous efficiency and wide temperature range.

### SUMMARY

In an aspect, a display substrate is provided. The display substrate includes a plurality of pixel driving circuits, and a pixel driving circuit includes at least a first transistor and a storage capacitor. The display substrate further includes: a substrate, a first gate conductive layer located on the substrate, a second gate conductive layer located on the first gate conductive layer, and a first source-drain conductive layer located on the second gate conductive layer. The first transistor includes a first gate pattern located in the first gate conductive layer, and the first gate pattern is also used as a first electrode plate of the storage capacitor. The storage capacitor includes a second electrode plate located in the second gate conductive layer; and orthographic projections, on the substrate, of the second electrode plate and the first electrode plate partially overlap. The first source-drain conductive layer includes at least one conductive pattern, and a conductive pattern is electrically connected to the second electrode plate. The conductive pattern includes a sub-portion; and orthographic projections, on the substrate, of the sub-portion and the first electrode plate overlap.

In some embodiments, the second gate conductive layer includes a first connection pattern that is spaced apart from the second electrode plate, and the first connection pattern is electrically connected to the first electrode plate. Orthographic projections, on the substrate, of the first connection pattern and the sub-portion overlap.

In some embodiments, the pixel driving circuit further includes a second transistor, and the second transistor includes a second gate pattern located in the first gate conductive layer. An orthographic projection of the second gate pattern on the substrate is located within an orthographic projection of the conductive pattern on the substrate.

In some embodiments, the display substrate further includes a second source-drain conductive layer located on the first source-drain conductive layer. The second source-drain conductive layer includes data lines extending in a first direction, the first direction being parallel to a plane where the substrate is located. The orthographic projection of the second gate pattern on the substrate is located within the orthographic projection of the conductive pattern on the substrate, and is located within an orthographic projection of a data line on the substrate.

In some embodiments, the pixel driving circuit further includes a second transistor; the display substrate further includes a semiconductor layer located between the substrate and the first gate conductive layer; the first transistor includes a first active pattern located in the semiconductor layer; the first active pattern includes a first connection portion and a first channel region sequentially arranged in a first direction, the first direction being parallel to a plane where the substrate is located; orthographic projections, on the substrate, of the first channel region, the first electrode plate and the second electrode plate partially overlap; the first connection portion is electrically connected to the conductive pattern; the second transistor includes a second active pattern located in the semiconductor layer, the second active pattern includes a second connection portion, and the second connection portion is electrically connected to the first electrode plate.

In some embodiments, there exist a plurality of conductive patterns, and the plurality of conductive patterns are arranged in a plurality of rows and a plurality of columns; each row of conductive patterns is arranged in a second direction, and each column of conductive patterns is arranged in a third direction, the second direction and the third direction intersecting and both being parallel to the plane where the substrate is located; the first source-drain conductive layer further includes a plurality of first power supply voltage signal lines extending in the second direction; and a first power supply voltage signal line is electrically connected to conductive patterns in a same row.

In some embodiments, the first power supply voltage signal line and the conductive patterns electrically connected to the first power supply voltage signal line are of an integrated structure.

In some embodiments, orthographic projections, on the substrate, of the first connection portion and the second electrode plate do not overlap; the first connection portion is electrically connected to the first power supply voltage signal line, and is electrically connected to the conductive pattern through the first power supply voltage signal line.

In some embodiments, there exist a plurality of conductive patterns, and the plurality of conductive patterns are arranged in a plurality of rows and a plurality of columns; each row of conductive patterns is arranged in a second direction, and each column of conductive patterns is arranged in a third direction, the second direction and the third direction intersecting and both being parallel to the plane where the substrate is located; and conductive patterns located in a same column are electrically connected to constitute a first power supply voltage signal line.

In some embodiments, the conductive patterns located in the same column are of an integrated structure.

In some embodiments, orthographic projections, on the substrate, of the first connection portion and the second electrode plate overlaps; the first connection portion is electrically connected to the second electrode plate, and is electrically connected to the conductive pattern through the second electrode plate.

In some embodiments, a plurality of second electrode plates are arranged in a plurality of rows and a plurality of columns, each row of second electrode plates is arranged in the second direction, and each column of second electrode plates is arranged in the third direction; and second electrode plates located in a same row are electrically connected.

In some embodiments, there exist a plurality of first active patterns; the plurality of first active patterns are arranged in a plurality of rows and a plurality of columns, each row of first active patterns is arranged in a second direction, and each column of first active patterns is arranged in a third direction, the second direction and the third direction intersecting and both being parallel to the plane where the substrate is located; and first connection portions of first active patterns located in a same row are connected.

In some embodiments, the plurality of pixel driving circuits are arranged in a plurality of rows and a plurality of columns, each row of pixel driving circuits is arranged in a second direction, and each column of pixel driving circuits is arranged in a third direction; and any two adjacent rows of pixel driving circuits are arranged in symmetry.

In some embodiments, the display substrate further includes a second source- drain conductive layer located on the first source-drain conductive layer. The second source-drain conductive layer includes data lines extending in the first direction. The second active pattern further includes a third connection portion, the third connection portion and the second connection portion are respectively located at two ends of the second active pattern, and the third connection portion is electrically connected to a data line. In a 2N-th row of pixel driving circuits and a (2N+1)-th row of pixel driving circuits, third connection portions of two pixel driving circuits located in a same column are of an integrated structure, N being a positive integer.

In some embodiments, in a 2N-th row of pixel driving circuits and a (2N-1)-th row of pixel driving circuits, first connection portions of two pixel driving circuits located in a same column are of an integrated structure, N being a positive integer.

In some embodiments, in a case where the first source-drain conductive layer further includes a plurality of first power supply voltage signal lines extending in the second direction, a first power supply voltage signal line electrically connected to conductive patterns of a 2N-th row of pixel driving circuits and a first power supply voltage signal line electrically connected to conductive patterns of a (2N-1)-th row of pixel driving circuits are of an integrated structure, N being a positive integer.

In another aspect, a display device is provided. The display device includes the display substrate as described in any of the above embodiments.

In yet another aspect, a method for manufacturing a display substrate is provided. The display substrate includes a plurality of pixel driving circuits, and a pixel driving circuit includes at least a first transistor and a storage capacitor. The method includes: providing a substrate; forming a first gate conductive layer on the substrate, wherein the first transistor includes a first gate pattern located in the first gate conductive layer, and the first gate pattern is also used as a first electrode plate of the storage capacitor; forming a second gate conductive layer on the first gate conductive layer, wherein the storage capacitor includes a second electrode plate located in the second gate conductive layer, and orthographic projections, on the substrate, of the second electrode plate and the first electrode plate partially overlap; and forming a first source-drain conductive layer on the second gate conductive layer, wherein the first source-drain conductive layer includes a conductive pattern, and the conductive pattern is electrically connected to the second electrode plate. The conductive pattern includes a sub-portion; orthographic projections, on the substrate, of the sub-portion and the first electrode plate overlap; and orthographic projections, on the substrate, of the sub-portion and the second electrode plate do not overlap.

In some embodiments, the pixel driving circuit further includes a second transistor. Before forming the first gate conductive layer, the method further includes: forming a semiconductor layer on the substrate; and forming a first gate insulating film on the semiconductor layer. After forming the first gate conductive layer and before forming the second gate conductive layer, the method further includes: forming a second gate insulating film on the first gate conductive layer; forming a first mask pattern on the second gate insulating film; etching a to-be-formed display substrate through the first mask pattern, so as to form a first via hole that penetrates the first gate insulating film and the second gate insulating film and exposes a part of the semiconductor layer and a second via hole that penetrates the second gate insulating film and exposes a part of the first gate conductive layer; cleaning the to-be-formed display substrate using a cleaning solution; and removing the first mask pattern.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display device, in accordance with some embodiments of the present disclosure;

FIG. 2 is a structural diagram of a display substrate, in accordance with some embodiments of the present disclosure;

FIG. 3 is a structural diagram of a pixel driving circuit, in accordance with some embodiments of the present disclosure;

FIG. 4 is a structural diagram of a display substrate, in accordance with an implementation;

FIG. 5 is a structural diagram of a display substrate, in accordance with another implementation;

FIG. 6A is a top view of some film layers in a display substrate, in accordance with some embodiments of the present disclosure;

FIG. 6B is a sectional view taken along the AA line in FIG. 6A;

FIGS. 6C to 6O are top views of different film layers in a display substrate, in accordance with some embodiments of the present disclosure;

FIG. 6P is a sectional view taken along the BB line in FIG. 6A;

FIG. 6Q is a sectional view taken along the CC line in FIG. 6A;

FIGS. 7A to 7K are top views of different film layers in another display substrate, in accordance with some embodiments of the present disclosure;

FIG. 8 is a sectional view taken along the DD line in FIG. 7A;

FIG. 9 is a top view of some other film layers in a display substrate, in accordance with some embodiments of the present disclosure;

FIG. 10A is a top view of yet some other film layers in a display substrate, in accordance with some embodiments of the present disclosure;

FIG. 10B is a sectional view taken along the EE line in FIG. 10A;

FIG. 11 is a sectional view taken along the FF line in FIG. 9;

FIG. 12 is a top view of yet some other film layers in a display substrate, in accordance with some embodiments of the present disclosure;

FIG. 13 is a top view of yet some other film layers in a display substrate, in accordance with some embodiments of the present disclosure;

FIG. 14 is a sectional view taken along the GG line in FIG. 9;

FIG. 15 is a flowchart of a method for manufacturing a display substrate, in accordance with some embodiments of the present disclosure;

FIGS. 16A to 16C are sectional views of to-be-formed display substrates in steps of a method for manufacturing a display substrate, in accordance with some embodiments of the present disclosure; and

FIG. 17 is a flowchart of a method for manufacturing a display substrate, in accordance with some embodiments of the present disclosure.

### DETAILED DESCRIPTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” and “second” may explicitly or implicitly include one or more of the features. In the description of the embodiments of the present disclosure, the term “multiple”, “a plurality of” or “the plurality of” means two or more unless otherwise specified.

In the description of some embodiments, the term “connected” and derivatives thereof may be used. The term “connected” should be understood in a broad sense. For example, the term “connected” may represent a fixed connection, a detachable connection, or a one-piece connection; alternatively, the term “connected” may represent a direct connection, or an indirect connection through an intermediate medium. The embodiments disclosed herein are not necessarily limited to the content herein.

The phrase “A and/or B” includes the following three combinations: only A, only B, and a combination of A and B.

In addition, the phrase “based on” used is meant to be open and inclusive, since a process, step, calculation or other action that is “based on” one or more of the stated conditions or values may, in practice, be based on additional conditions or values exceeding those stated.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

In circuit structures (e.g., pixel driving circuits) provided in the embodiments of the present disclosure, transistors used in the circuit structures may be thin film transistors (TFTs), metal oxide semiconductor (MOS) transistors, or other switching devices with same properties, and the embodiments of the present disclosure are described by taking the thin film transistors as an example.

In the circuit structure provided in the embodiments of the present disclosure, a first electrode of a transistor used is one of a source and a drain of the transistor, and a second electrode of each transistor used is the other of the source and the drain. Since the source and the drain of the transistor may be symmetrical in structure, there may be no difference in structure between the source and the drain of the transistor. That is to say, the first electrode and the second electrode of the transistor in the embodiments of the present disclosure may be the same in structure. For example, in a case where the transistor is a P-type transistor, the first electrode of the transistor is the source, and the second electrode of the transistor is the drain. For example, in a case where the transistor is an N-type transistor, the first electrode of the transistor is the drain, and the second of the transistor is the source.

In the circuit structure provided in the embodiments of the present disclosure, nodes such as a first node and a second node do not represent actual components, but represent junction points of relevant couplings in a circuit diagram. That is, these nodes are equivalent to the junction points of the relevant couplings in the circuit diagram.

Transistors included in the circuit structure provided in the embodiments of the present disclosure may all be N-type transistors or P-type transistors; or part of the transistors may be N-type transistors, and another part of the transistors may be P-type transistors. The P-type transistor may be turned on under control of a low-level signal, and the N-type transistor may be turned on under control of a high-level signal.

The following embodiments are described by taking an example in which the transistors are P-type transistors.

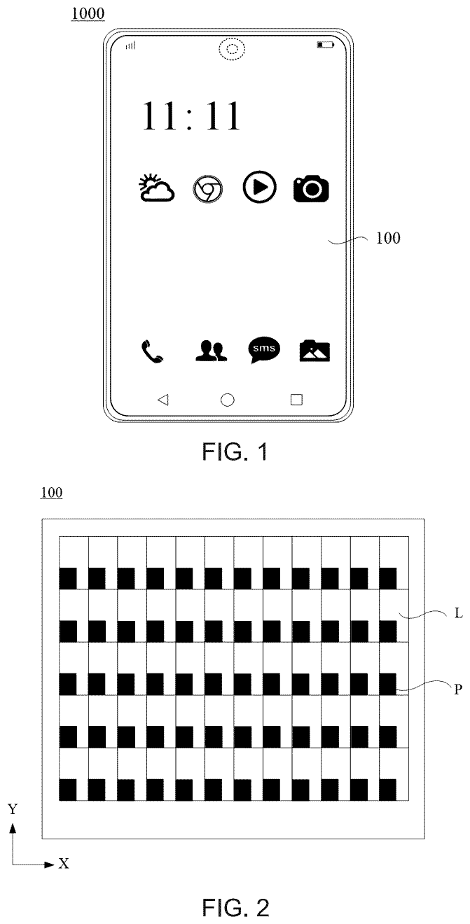

As shown in FIG. 1, some embodiments of the present disclosure provide a display substrate 100 and a display device 1000. The display substrate 100 and the display device 1000 will be described below.

Some embodiments of the present disclosure provide a display device 1000. The display device 1000 may be any device that displays images whether in motion (e.g., videos) or stationary (e.g., still images) and whether textual or graphical. More specifically, it is expected that the embodiments may be implemented in or associated with a variety of electronic devices. The variety of electronic devices may include (but are not limit to), for example, mobile telephones, wireless devices, personal data assistants (PDAs), hand-held or portable computers, GPS receivers/navigators, cameras, MP4 video players, video cameras, game consoles, watches, clocks, calculators, TV monitors, flat panel displays, computer monitors, car displays (such as odometer displays), navigators, cockpit controllers and/or displays, camera view displays (such as rear view camera displays in vehicles), electronic photos, electronic billboards or signs, projectors, architectural structures, packagings, and aesthetic structures (such as displays for images of a piece of jewelry).

In some embodiments, as shown in FIG. 1, the display device 1000 includes a display substrate 100.

For example, the display device 1000 further includes a frame, a display driver integrated circuit (IC) and other electronic components.

For example, the display driver IC may provide data signals for the display substrate 100. The data signals include display data signals and sensing data signals. Thus, the display brightness of the display substrate 100 may be controlled by using the display data signals.

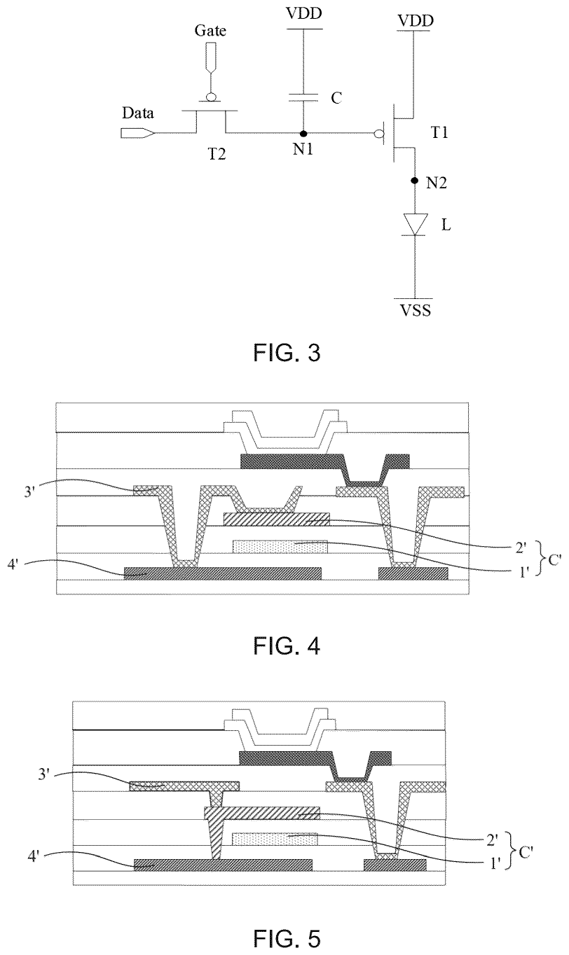

In some embodiments, as shown in FIG. 2, the display substrate 100 includes a plurality of pixel driving circuits P and a plurality of light-emitting devices L.

For example, the plurality of pixel driving circuits P and the plurality of light-emitting devices L may be electrically connected in a one-to-one correspondence. For another example, in some embodiments of the present disclosure, a single pixel driving circuit P may be electrically connected to multiple light-emitting devices L, or multiple pixel driving circuits P may be electrically connected to a single light-emitting device L.

In the present disclosure, a structure of the display substrate 100 will be described below by considering an example in which a single pixel driving circuit P is electrically connected to a single light-emitting device L.

For example, in the display substrate 100, each light-emitting device L may emit light under drive of a corresponding pixel driving circuit P. Light emitted by the plurality of light-emitting devices L cooperates to realize the display function of the display substrate 100.

For example, the light-emitting devices L are organic light-emitting diode (OLED) devices, light-emitting diode (LED) devices, or the like.

Some embodiments of the present disclosure will be described below by taking an example where the light-emitting devices L are OLED devices.

For example, the light-emitting device L may include a first electrode, a light-emitting functional layer, and a second electrode that are sequentially stacked. The light-emitting functional layer may include a light-emitting layer. Optionally, the light-emitting functional layer may further include at least one of: a hole injection layer, a hole transport layer, an electron transport layer, or an electron injection layer.

For example, the first electrode may be one of an anode and a cathode, and the second electrode may be another of the anode and the cathode, which will not be limited in the present disclosure.

Some of the following embodiments will be described by taking an example where the first electrode is the anode and the second electrode is the cathode.

Since a common voltage is applied to the second electrode of the light-emitting device L and the corresponding pixel driving circuit P applies a driving voltage to the first electrode of the light-emitting device L, an electric field may be created between the first electrode and the second electrode. The electric field may drive different carriers (i.e., holes and electrons) to recombine in the light-emitting layer, thereby causing the light-mitting e device L to emit light.

For example, the pixel driving circuit P and the light emitting device L electrically connected thereto constitute a sub-pixel in the display substrate 100. The greater the density of sub-pixels in the display substrate 100 (that is, the higher the pixels per inch (PPI) of the display substrate 100), the clearer the image displayed by the display substrate 100, and the better the display effect of the display substrate 100.

It will be noted that, the structure of the pixel driving circuit P varies, which may be determined according to actual needs. For example, the structure of the pixel driving circuit P may include a “2T1C” structure, a “3T1C” structure, a “4T1C” structure, a “6T1C” structure, a “7T1C” structure, a “6T2C” structure, a “7T2C” structure, or an “8T2C” structure. Here, “T” represents a transistor, a number preceding “T” represents the number of transistors, “C” represents a storage capacitor, and a number preceding “C” represents the number of storage capacitors.

Some embodiments of the present disclosure will be described by taking an example where the pixel driving circuit P is of the “2T1C” structure.

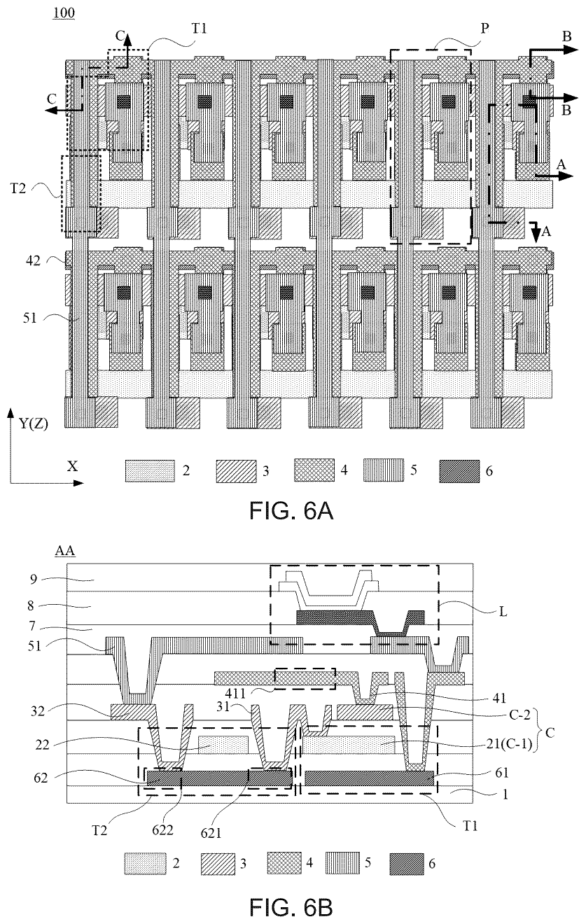

As shown in FIG. 3, the pixel driving circuit P includes a first transistor T1, a second transistor T2, and a storage capacitor C.

A first electrode of the second transistor T2 is connected to a data line (Data in FIG. 3), a second electrode of the second transistor T2 is connected to a first node N1, and a gate of the second transistor T2 is connected to a gate line (Gate in FIG. 3). The second transistor T2 is used to transmit a data signal transmitted by the data line to the first node under control of a gate signal transmitted by the gate line.

A first electrode of the first transistor T1 is connected to a first power supply voltage signal line (VDD in FIG. 3), a second electrode of the first transistor T1 is connected to a second node N2, and a gate of the first transistor T1 is connected to the first node N1. The first transistor T1 is used to transmit a first power supply voltage signal transmitted by the first power supply voltage signal line to the second node N2 under control of an electrical signal at the first node N1, and to provide a driving current for the light-emitting device L to drive the light-emitting device L to emit light. The first transistor T1 may also be referred to as a driving transistor (DTFT). A first electrode of the storage capacitor C is connected to the first node N1, a second electrode of the storage capacitor C is connected to the first power supply voltage signal line, and the storage capacitor C is used to store the data signal transmitted to the first node.

The first electrode of the light-emitting device L is connected to the second node N2, and the second electrode of the light-emitting device L is connected to a second power supply voltage signal terminal (VSS in FIG. 3). The light-emitting device L is used to emit light due to the first power supply voltage signal transmitted to the second node N2 and a second power supply voltage signal provided by the second power supply voltage signal terminal.

Due to the characteristics of transistors, as shown in FIG. 3, the second transistor T2 has a certain leakage current in an turn-off state, which will cause the data signal stored in the storage capacitor C to be unstable, which in turn causes the driving current provided by the first transistor T1 for the light-emitting device L to be unstable, resulting in unstable light emission of the light-emitting device L. By increasing a capacitance value of the storage capacitor C, the stability of the data signal stored in the storage capacitor C may be enhanced.

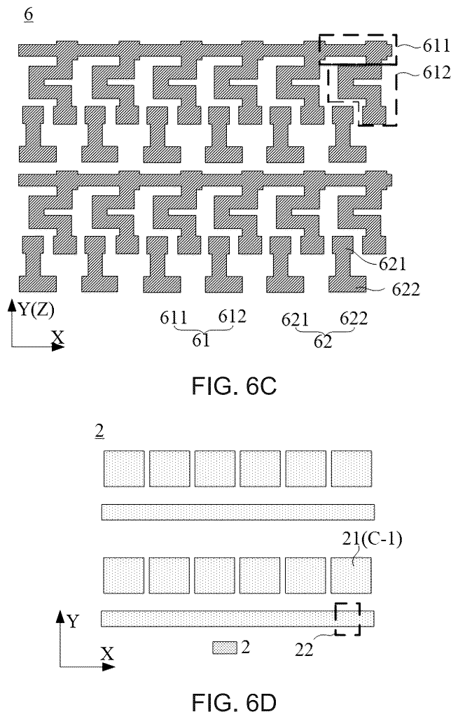

In an implementation, as shown in FIG. 4, a storage capacitor C′ of a pixel driving circuit is composed of a first electrode plate 1′ located in a first gate layer and a second electrode plate 2′ located in a second gate layer, and the first electrode plate 1′ is also used to constitute a gate of a first transistor. A first power supply voltage signal line 3′ and a data line (not shown in FIG. 4) are both arranged in a source-drain conductive layer. The second electrode plate 2′ is connected to the first power supply voltage signal line 3′, thereby realizing the connection between the second electrode of the storage capacitor C′ and the first power supply voltage signal line. The first power supply voltage signal line 3′ is also connected to a first active pattern 4′ located in an active layer through a via hole, and the first active pattern 4′ is used to form a channel region, a first electrode and a second electrode of the first transistor, thereby realizing the connection between the first electrode of the first transistor and the first power supply voltage signal line.

By increasing an overlapping area of the first electrode plate 1′ and the second electrode plate 2′, the capacitance value of the storage capacitor C′ may be increased. However, as shown in FIG. 4, since the first power supply voltage signal line 3′ is connected to the first active pattern 4′ located in the active layer through the via hole, a portion of the first power supply voltage signal line 3′ for connecting to the first active pattern 4′ needs to be staggered with the first electrode plate 1′ and the second electrode plate 2′ on a plane where the display substrate is located, which will result in a large area occupied by the first power supply voltage signal line 3′, the first electrode plate 1′ and the second electrode plate 2′ on the plane where the display substrate is located. Therefore, a single pixel driving circuit occupies a large space in the display substrate. Only a small number of pixel driving circuits can be arranged in the display substrate of the same area, causing difficulty in realizing high PPI display of the display substrate (for example, the PPI is 1500 or more than 1500).

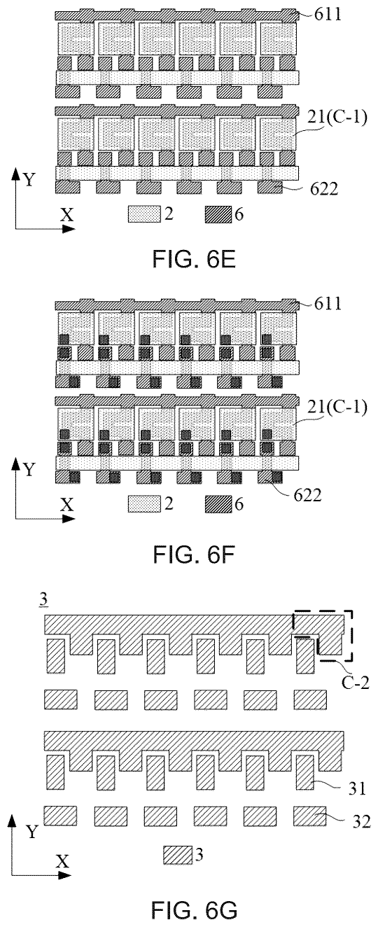

In another implementation, as shown in FIG. 5, the first power supply voltage signal line 3′ is connected to the second electrode plate 2′, and the second electrode plate 2′ is directly connected to the first active pattern 4′ located in the active layer through a via hole. Compared with the above-mentioned implementation, it may be possible to reduce the number of via holes for connecting first power supply voltage signal lines 3′ to first active patterns 4′, reduce the area occupied by the via holes for connecting the first power supply voltage signal lines 3′ to the first active patterns 4′ on the plane where the display substrate is located, and in turn reduce the area occupied by the first power supply voltage signal lines 3′, the first electrode plates 1′ and the second electrode plates 2′ on the plane where the display substrate is located. However, in a high PPI display substrate, each pixel driving circuit has a small area, and accordingly, the areas of the first electrode plate 1′ and the second electrode plate 2′ in the pixel driving circuit are also small. Therefore, due to the limitation of the areas of the first electrode plate 1′ and the second electrode plate 2′, the capacitance value of the storage capacitor C′ cannot be further increased.

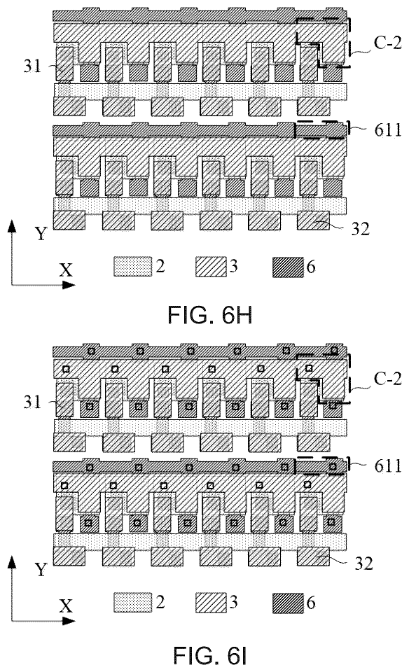

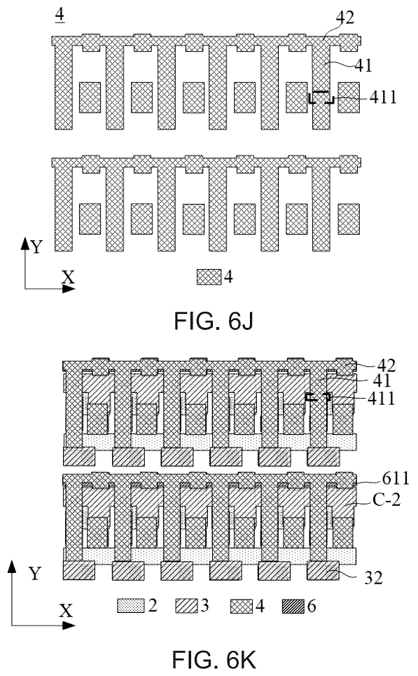

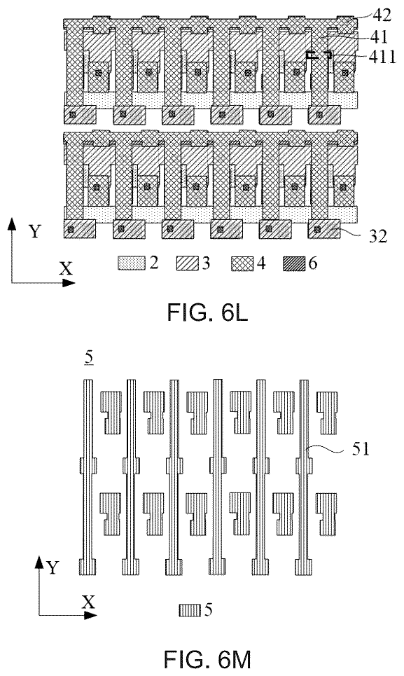

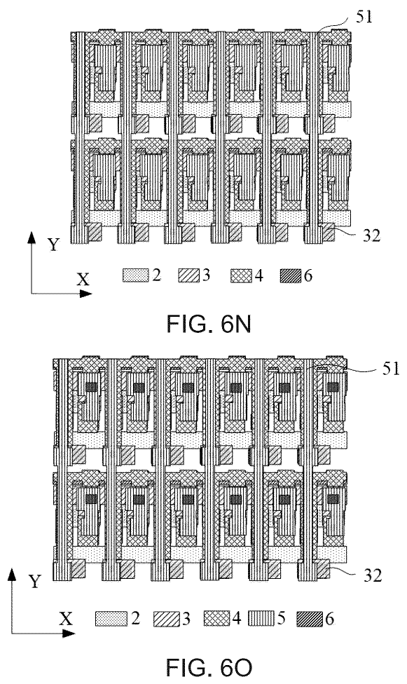

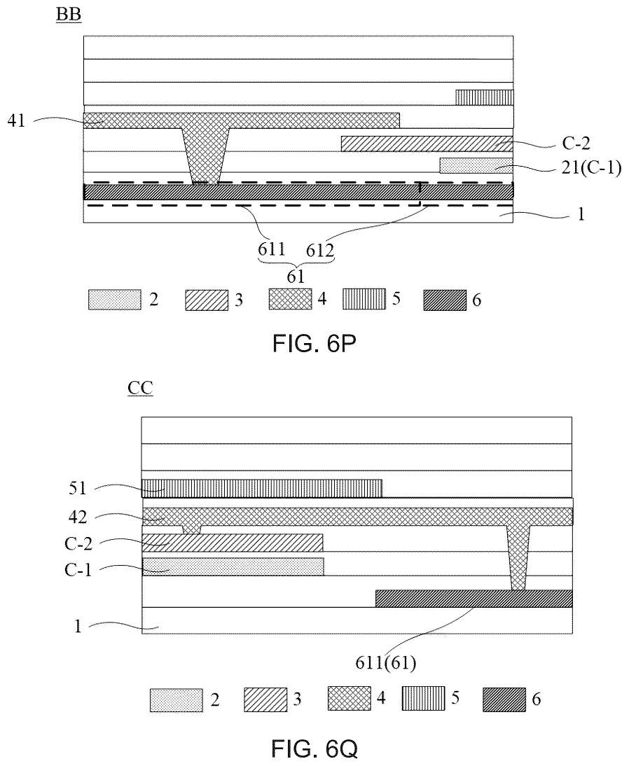

FIG. 6A is a top view of a display substrate in some embodiments of the present disclosure. FIG. 6B is a sectional view taken along the AA line in FIG. 6A. As shown in FIG. 6B, the display substrate 100 provided in some embodiments of the present disclosure further includes: a substrate 1, a first gate conductive layer 2, a second gate conductive layer 3, and a first source-drain conductive layer 4.

For example, a structure of the substrate 1 varies, which may be set according to actual needs.

For example, the substrate 1 may be of a single-layer structure.

For example, the substrate 1 may be a rigid substrate. The rigid substrate may be, for example, a glass substrate or a polymethyl methacrylate (PMMA) substrate. In this case, the display substrate 100 may be a rigid display substrate.

As another example, the substrate 1 may be a flexible substrate. The flexible substrate may be, for example, a polyethylene terephthalate (PET) substrate, a polyethylene naphthalate (PEN) substrate or a polyimide (PI) substrate. In this case, the display substrate 100 may be a flexible display substrate.

For example, the substrate 1 may be of a multi-layer structure. That is, the substrate 1 includes a plurality of sub-film layers, and a material of each sub-film layer may be the same or different.

In some examples, as shown in FIG. 6B, the first gate conductive layer 2 is located on the substrate 1. The first transistor T1 includes a first gate pattern 21 located in the first gate conductive layer 2. The first gate pattern 21 is also used as the first electrode plate C-1 of the storage capacitor C. The second gate conductive layer 3 is located on the first gate conductive layer 2. The storage capacitor C includes the second electrode plate C-2 located in the second gate conductive layer 3. Orthographic projections, on the substrate 1, of the second electrode plate C-2 and the first electrode plate C-1 partially overlap. The first source-drain conductive layer 4 is located on the second gate conductive layer 3. The first source-drain conductive layer 4 includes conductive pattern(s) 41. A conductive pattern 41 is electrically connected to the second electrode plate C-2.

For example, the first gate conductive layer 2, the second gate conductive layer 3, and the first source-drain conductive layer 4 are each made of a conductive material. The first gate conductive layer 2, the second gate conductive layer 3, and the first source-drain conductive layer 4 may be, for example, made of the same material. The first gate conductive layer 2, the second gate conductive layer 3, and the first source-drain conductive layer 4 may be made of different materials.

For example, the first gate conductive layer 2, the second gate conductive layer 3, and the first source-drain conductive layer 4 may be made of a metal material, such as aluminum (Al), silver (Ag), copper (Cu), chromium (Cr), or the like.

Correspondingly, an insulating layer is further provided between the above-mentioned film layers. For example, and the insulating layer may be made of silicon oxide, silicon nitride, silicon oxynitride, or the like.

As shown in FIG. 6B, the conductive pattern 41 is electrically connected to the second electrode plate C-2. Therefore, providing the conductive pattern 41 is equivalent to increasing the area of the second electrode plate C-2 of the storage capacitor C.

In some examples, the conductive pattern 41 includes a sub-portion 411. Orthographic projections, on the substrate 1, of the sub-portion 411 and the first electrode plate C-1 overlap.

For example, the sub-portion 411 overlapping the first electrode plate C-1 means that, in a direction perpendicular to the substrate 1, the sub-portion 411 and the first electrode plate C-1 have opposite regions.

In this way, an overlapping area of the sub-portion 411 and the first electrode plate C-1 may be increased in addition to the original overlapping area of the first electrode plate C-1 and the second electrode plate C-2, which increases the capacitance value of the storage capacitor C. Thus, it may be possible to enhance the stability of the data signal stored in the storage capacitor C in the pixel driving circuit P. That is, it is conducive to stabilizing a potential of the first gate pattern 21 (gate) of the first transistor T1.

Therefore, in the display substrate 100 in the embodiments of the present disclosure, providing the conductive pattern 41 electrically connected to the second electrode plate C-2 is equivalent to increasing the area of the second electrode plate C-2 of the storage capacitor C. Moreover, since the orthographic projections, on the substrate 1, of the sub-portion 411 of the conductive pattern 41 and the first electrode plate C-1 overlap, the overlapping area of the sub-portion 411 and the first electrode plate C-1 may be increased in addition to the original overlapping area of the first electrode plate C-1 and the second electrode plate C-2, which increases the capacitance value of the storage capacitor C. Thus, it may be possible to enhance the stability of the data signal stored in the storage capacitor C in the pixel driving circuit P. That is, it is conducive to stabilizing the potential of the first gate pattern 21 (gate) of the first transistor T1.

In addition, in this way, it may be possible to avoid increasing the areas of the first electrode plate C-1 and the second electrode plate C-2 in the display substrate 100, avoid increasing the space occupied by the first electrode plate C-1 in the first gate conductive layer 2, avoid increasing the space occupied by the second electrode plate C-2 in the second gate conductive layer 3, and in turn avoid increasing the space occupied by a single pixel driving circuit P in the display substrate 100. Thus, it is conducive to realizing the high PPI display of the display substrate 100.

In some embodiments, the second gate conductive layer 3 further includes a first connection pattern 31 spaced apart from the second electrode plate C-2, and the first connection pattern 31 is electrically connected to the first electrode plate C-1. Orthographic projections, on the substrate 1, of the first connection pattern 31 and the sub-portion 411 overlap.

The first connection pattern 31 is electrically connected to the first electrode plate C-1, which is equivalent to increasing the area of the first electrode plate C-1 of the storage capacitor C.

In this way, an overlapping area of the first connection pattern 31 and the sub-portion 411 is increased, which is equivalent to increasing the overlapping area of the first electrode plate C-1 and the second electrode plate C-2 of the storage capacitor C, which in turn increases the capacitance value of the storage capacitor C. Thus, it may be possible to enhance the stability of the data signal stored in the storage capacitor C in the pixel driving circuit P.

In some embodiments, the second transistor T2 includes a second gate pattern 22 located in the first gate conductive layer 2. An orthographic projection of the second gate pattern 22 on the substrate 1 is located within an orthographic projection of the conductive pattern 41 on the substrate 1.

In this way, in the direction perpendicular to the substrate 1, the conductive pattern 41 may provide shielding for the second gate pattern 22, thereby preventing a signal transmitted on a line (e.g., a data line 51 described below) that is located on a side of the conductive pattern 41 away from the second gate pattern 22 from causing crosstalk to a signal transmitted by the second gate pattern 22, and in turn avoiding affecting the stability of the signal transmitted by the second gate pattern 22.

In some embodiments, as shown in FIG. 6A, the display substrate 100 further includes a second source-drain conductive layer 5 located on the first source-drain conductive layer 4. The second source-drain conductive layer 5 includes data lines 51 extending in a first direction Z. The first direction Z is parallel to a plane where the substrate 1 is located.

For example, the second source-drain conductive layer 5 is made of a conductive material. The second source-drain conductive layer 5 and the first source-drain conductive layer 4 may be, for example, made of the same material. Alternatively, the second source-drain conductive layer 5 and the first source-drain conductive layer 4 may be made of different materials.

For example, the data lines 51 are used for transmitting data signals.

In some examples, the orthographic projection of the second gate pattern 22 on the substrate 1 is located within the orthographic projection of the conductive pattern 41 on the substrate 1, and is located within an orthographic projection of a data line 51 on the substrate 1.

In this way, as shown in FIG. 6B, the conductive pattern 41 located between the second gate pattern 22 and the data line 51 may provide shielding for the second gate pattern 22 and the data line 51, thereby avoiding interference between signals transmitted by the second gate pattern 22 and the data line 51.

In some embodiments, as shown in FIG. 6A, the display substrate 100 further includes a semiconductor layer 6 located between the substrate 1 and the first gate conductive layer 2.

For example, a material of the semiconductor layer 6 includes amorphous silicon, monocrystalline silicon, polycrystalline silicon, or a metal oxide semiconductor material.

In some examples, as shown in FIG. 6C, the first transistor T1 includes a first active pattern 61 located in the semiconductor layer 6, and the first active pattern 61 includes a first connection portion 611 and a first channel region 612 sequentially arranged in the first direction Z. As shown in FIG. 6P, orthographic projections, on the substrate 1, of the first channel region 612, the first electrode plate C-1, and the second electrode plate C-2 partially overlap. The first connection portion 611 is electrically connected to the conductive pattern 41. As shown in FIG. 6B, the second transistor T2 includes a second active pattern 62 located in the semiconductor layer 6. The second active pattern 62 includes a second connection portion 621. The second connection portion 621 is electrically connected to the first electrode plate C-1.

It will be noted that, an orthographic projection of the semiconductor layer 6 on the substrate 1 overlaps with an orthographic projection of the first gate conductive layer 2 on the substrate 1. After the first gate conductive layer 2 is formed on a side of the semiconductor layer 6 away from the substrate 1, the semiconductor layer 6 is doped using the first gate conductive layer 2 as a mask. Thus, a part of the semiconductor layer 6 covered by the first gate conductive layer 2 is not doped and still has semiconductor characteristics, which constitutes active patterns of all the transistors; and a part of the semiconductor layer 6 not covered by the first gate conductive layer 2 is doped and has conductor characteristics, which constitutes conductive portions, and the conductive portions may serve as first electrodes or second electrode of all the transistors. A part of the first gate conductive layer 2 overlapping the semiconductor layer 6 constitutes gate patterns (i.e., gates) of all the transistors.

As shown in FIGS. 6C to 60, in the display substrate 100 shown in FIG. 6A, FIG. 6C is a top view of the semiconductor layer 6, FIG. 6D is a top view of the first gate conductive layer 2, FIG. 6E is a top view of the semiconductor layer 6 and the first gate conductive layer 2 that are stacked, FIG. 6F is a top view of a structure after an insulating layer is formed on the first gate conductive layer 2 and holes are formed in the insulating layer, FIG. 6G is a top view of the second gate conductive layer 3, FIG. 6H is a top view of the semiconductor layer 6, the first gate conductive layer 2 and the second gate conductive layer 3 that are stacked, FIG. 6I is a top view a structure after an insulating layer is formed on the second gate conductive layer 3 and holes are formed in the insulating layer, FIG. 6J is a top view of the first source-drain conductive layer 4, FIG. 6K is a top view of the semiconductor layer 6, the first gate conductive layer 2, the second gate conductive layer 3 and the first source-drain conductive layer 4 that are stacked, FIG. 6L is a top view of a structure after an insulating layer is formed on the first source-drain conductive layer 4 and holes are formed in the insulating layer, FIG. 6M is a top view of the second source-drain conductive layer 5, FIG. 6N is a top view of the semiconductor layer 6, the first gate conductive layer 2, the second gate conductive layer 3, the first source-drain conductive layer 4 and the second source-drain conductive layer 5 that are stacked, and FIG. 6O is a top view of a structure after an insulating layer is formed on the second source-drain conductive layer 5 and holes are formed in the insulating layer. In the above figures, in order to clearly illustrate the relationship between the film layers, the insulating layers are not shown in the above figures.

As shown in FIG. 6P, the first channel region 612, the first electrode plate C-1 and the second electrode plate C-2 partially overlap. Therefore, the first electrode plate C-1 may be used as the gate of the first transistor T1, and is also used as the second electrode plate C-2 of the storage capacitor C.

For example, as shown in FIG. 6P, the conductive pattern 41 is directly electrically connected to the first connection portion 611 through a via hole. In this way, the electrical signal transmitted by the conductive pattern 41 may be transmitted to the first active pattern 61 of the first transistor T1 through the first connection portion 611.

For example, as shown in FIG. 6B, the second connection portion 621 may be electrically connected to the first electrode plate C-1 through the first connection pattern 31. As shown in FIG. 3, in this way, a signal output by the second transistor T2 may be transmitted to the gate of the first transistor T1, so as to control a tun-on state of the first transistor T1.

In some embodiments, as shown in FIG. 6C, there are a plurality of first active patterns 61; the plurality of first active patterns 61 are arranged in multiple rows and multiple columns, first active patterns 61 in each row are arranged in a second direction X, and first active patterns 61 in each column are arranged in a third direction Y; the second direction X and the third direction Y intersect and are both parallel to the plane where the substrate 1 is located; and first connection portions 611 of multiple first active patterns 61 in the same row are connected.

For example, the first direction Z may be parallel to the third direction Y, or the first direction Z and the third direction Y may have an included angle therebetween. For the convenience of description, the embodiments of the present disclosure are described by taking an example in which the first direction Z is parallel to the third direction Y.

For example, the second direction X and the third direction Y intersecting indicates that the second direction X and the third direction Y have an included angle therebetween. The angle may be an arbitrary value not equal to zero. The embodiments of the present disclosure are described with the angle of 90°.

In this way, it may be possible to simplify the design and fabricating process of the first connection portions 611 of the first active patterns 61.

In some embodiments, as shown in FIG. 6C, the first connection portions 611 of multiple first active patterns 61 in the same row are of an integrated structure.

For example, “the integrated structure” means that two connected patterns are arranged in the same layer, and the two patterns are continuous and not separated.

In this way, it may be possible to make the structure of the first connection portions 611 of the plurality of first active patterns 61 more stable, and ensure that the connection between the first connection portions 611 is more stable.

In some embodiments, as shown in FIG. 6J, there are a plurality of conductive patterns 41, the plurality of conductive patterns 41 are arranged in multiple rows and multiple columns, conductive patterns 41 in each row are arranged in the second direction X, and conductive patterns 41 in each column are arranged in the third direction Y. The first source-drain conductive layer 4 further includes a plurality of first power supply voltage signal lines 42 extending in the second direction X. A first power supply voltage signal line 42 is electrically connected to multiple conductive patterns 41 in the same row.

For example, the first power supply voltage signal line 42 is used for transmitting first power supply voltage signals.

In this way, as shown in FIG. 6J, a first power supply voltage signal transmitted by a first power supply voltage signal line 42 may be transmitted to multiple conductive patterns 41 in the same row; and as shown in FIG. 6P, the first power supply voltage signal is transmitted to multiple first connection portions 611 in the same row through the conductive patterns 41, that is, transmitted to first transistors T1. In addition, as shown in FIG. 6B, the first power supply voltage signal transmitted by the first power supply voltage signal line may also be transmitted to second electrode plates C-2 of storage capacitors C through the conductive patterns 41. The first power supply voltage signal is a constant voltage signal. In this way, it may be conducive to maintaining the stability of the potential of the first electrode plate C-1 of the storage capacitor C. That is, it is conducive to stabilizing the potential of the first gate pattern 21 (gate) in the first transistor T1.

Moreover, in combination with FIGS. 6L and 6P, in the second direction X, the first power supply voltage signal line 42 and multiple first connection portions 611 located in the same row may constitute a parallel connection structure, thereby reducing the voltage drop of the first power supply voltage signal during transmission in the first power supply voltage signal line 42, and in turn ensuring the stability of the first power supply voltage signal transmitted to the first transistors T1 in the same row, which is conducive to reducing difference in display of pixels in the same row.

In some embodiments, as shown in FIG. 6J, the first power supply voltage signal line 42 and the conductive patterns 41 electrically connected to the first power supply voltage signal line 42 are of an integrated structure.

In this way, it may be possible to enhance the stability of connection between the first power supply voltage signal line 42 and the conductive patterns 41, and avoid setting connection lines between the first power supply voltage signal line 42 and the conductive patterns 41, and in turn simplify the design and fabricating process of the first power supply voltage signal lines 42 and the plurality of conductive patterns 41.

In some embodiments, as shown in FIG. 6H, orthographic projections, on the substrate, the first connection portion 611 and the second electrode plate C-2 do no overlap. As shown in FIG. 6Q, the first connection portion 611 is electrically connected to the first power supply voltage signal line 42, and is electrically connected to the conductive pattern 41 through the first power supply voltage signal line 42.

In this way, the first power supply voltage signal transmitted by the first power supply voltage signal line 42 may be transmitted to the first connection portion 611 of the first active pattern 61 of the first transistor T1 and also be transmitted to the second electrode plate C-2 of the storage capacitor C.

In some other examples, the first connection portion 611 and the conductive pattern 41 may be electrically connected in other ways.

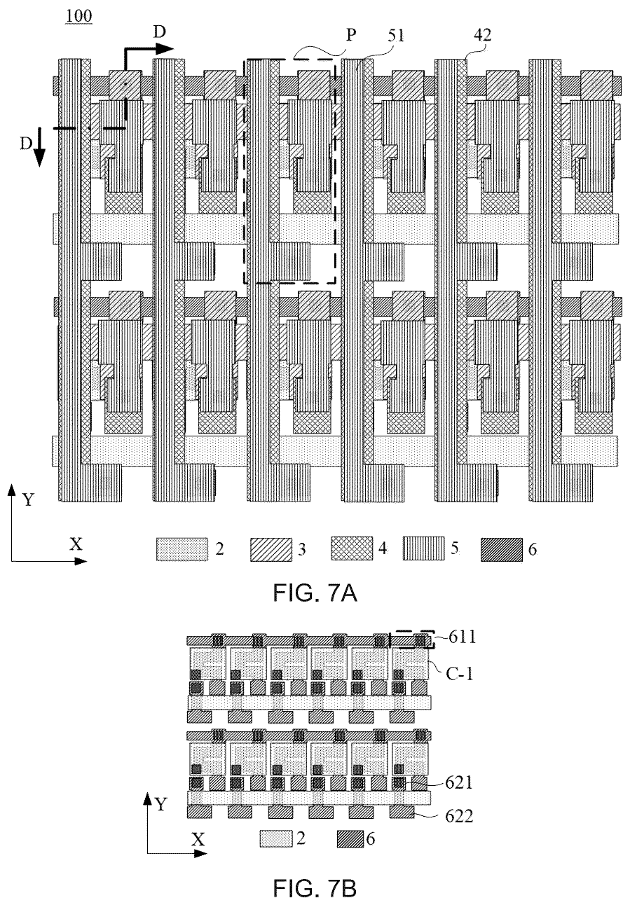

As shown in FIG. 7A, in the display substrate 100 in FIG. 7A, after the first gate conductive layer 2 is formed, the remaining film layers are different from those in FIGS. 6F to 6O. As shown in FIGS. 7B to 7K, FIG. 7B is a top view of a structure after an insulating layer is formed on the first gate conductive layer 2 and holes are formed in the insulating layer, and positions of holes of the insulating layer in FIG. 7B are different from positions of holes of the insulating layer in FIG. 6F; FIG. 7C is a top view of the second gate conductive layer 3, and a shape of the second electrode C-2 in FIG. 7C is different from a shape of the second electrode C-2 in FIG. 6G; FIG. 7D is a top view of the semiconductor layer 6, the first gate conductive layer 2 and the second gate conductive layer 3 that are stacked; in FIG. 7D, the second electrode plate C-2 is electrically connected to the first conductive portion 611 through a via hole, while in FIG. 6H, the second electrode plate C-2 is disconnected from the first conductive portion 611; FIG. 7E is a top view of a structure after an insulating layer is formed on the second gate conductive layer 3 and holes are punched in the insulating layer, and positions of holes of the insulating layer in FIG. 7E are different from positions of holes of the insulating layer in FIG. 6I; FIG. 7F is a top view of the first source-drain conductive layer 4, and the arrangement of the first power supply voltage signal lines 42 in FIG. 7F is different from the arrangement of the first power supply voltage signal lines 42 in FIG. 6J; FIG. 7G is a top view of the semiconductor layer 6, the first gate conductive layer 2, the second gate conductive layer 3 and the first source-drain conductive layer 4 that are stacked; in FIG. 7G, the first power supply voltage signal line 42 is electrically connected to the second electrode C-2 through a via hole; in FIG. 6K, the first power supply voltage signal line 42 is electrically connected to the first conductive portion 611 through a via hole, and the second electrode C-2 is electrically connected to the conductive pattern 41 through a via hole; FIG. 7H is a top view of a structure after an insulating layer is formed on the first source-drain conductive layer 4 and holes are formed in the insulating layer, and positions of holes of the insulating layer in FIG. 7H are different from positions of holes of the insulating layer in FIG. 6L; FIG. 7I is a top view of the second source-drain conductive layer 5, and a shape of the data line 51 in FIG. 7I is different from a shape of the data line 51 in FIG. 6M; FIG. 7J is a top view of the semiconductor layer 6, the first gate conductive layer 2, the second gate conductive layer 3, the first source-drain conductive layer 4 and the second source-drain conductive layer 5 that are stacked; in FIG. 7J, the data line 51 is electrically connected to the third connection portion 622 through a via hole; in FIG. 6N, the data line 51 is electrically connected to the second connection pattern 32 through a via hole, and the second connection pattern 32 is further electrically connected to the third connection portion 622 through a via hole; and FIG. 7K is a top view of a structure after an insulating layer is formed on the second source-drain conductive layer 5 and holes are formed in the insulating layer. In the above figures, in order to clearly show the relationship between the film layers, the insulating layers are not shown in the above figures.

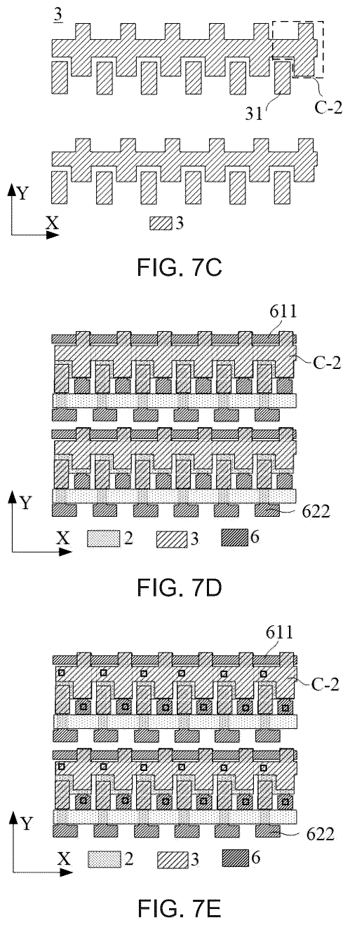

As shown in FIG. 8, the conductive pattern 41 is electrically connected to the second electrode plate C-2 through a via hole, and the second electrode plate C-2 is electrically connected to the first connection portion 611 through a via hole, thereby realizing electrical connection between the first connection portion 611 and the conductive pattern 41. As shown in FIG. 7G, through the above-mentioned arrangement, it may be possible to avoid setting the first power supply voltage signal line 42 on the first connection portion 611, and in turn saving the material of the first power supply voltage signal line 42 and reducing the space occupied by the first power supply voltage signal lines 42 in the first source-drain conductive layer 4.

In some embodiments, as shown in FIG. 7F, there are a plurality of conductive patterns 41, and the plurality of conductive patterns 41 are arranged in multiple rows in the third direction Y and arranged in multiple columns in the second direction X. Multiple conductive patterns 41 located in the same column are electrically connected to form a first power supply voltage signal line 42.

In this way, it may be possible to avoid setting the first power supply voltage signal line 42 in the second direction X and save the material. In addition, the space occupied by the first power supply voltage signal lines 42 in the display substrate 100 is reduced, which is conducive to realizing the high PPI display of the display substrate 100.

In some embodiments, as shown in FIG. 7F, multiple conductive patterns 41 located in the same column are of an integrated structure.

In this way, it may be possible to make the connection between the conductive patterns 41 more stable and simplify the design and fabrication difficulty of the conductive patterns 41.

In some embodiments, as shown in FIG. 8, orthographic projections, on the substrate 1, the first connection portion 611 and the second electrode plate C-2 overlap. The first connection portion 611 is electrically connected to the second electrode plate C-2, and is electrically connected to the conductive pattern 41 through the second electrode plate C-2.

In this way, it may be possible to realize electrical connection between the first connection portion 611 and the conductive pattern 41. Since multiple conductive patterns 41 located in the same column are electrically connected to form a first power supply voltage signal line 42, the first power supply voltage signal transmitted by the first power supply voltage signal line 42 may be transmitted to the first connection portions 611 through the second electrode plates C-2, that is, transmitted to the first transistors T1.

In some embodiments, as shown in FIG. 7C, a plurality of second electrode plates C-2 are arranged in multiple rows and multiple columns, each row of second electrode plates C-2 is arranged in the second direction X, and each column of second electrode plates C-2 is arranged in the third direction Y. Multiple second electrode plates in the same row are electrically connected.

In this way, multiple rows of second electrode plates C-2 and multiple columns of first power supply voltage signal lines 42 may constitute a mesh structure, and the first power supply voltage signals transmitted by the first power supply voltage signal lines 42 may be transmitted in the above-mentioned mesh structure. Therefore, it may be possible to further reduce the attenuation of the first power supply voltage signals during the transmission process in the first power supply voltage signal lines 42, which is conducive to reducing the difference of first power supply voltage signals transmitted to different pixel driving circuits P.

In some embodiments, as shown in FIGS. 6A and 7A, patterns of different pixel driving circuits P are arranged cyclically.

In this way, the design and fabrication difficulty of the patterns of the plurality of pixel driving circuits P may be simplified, which is conducive to fully utilizing the space of the display substrate 100.

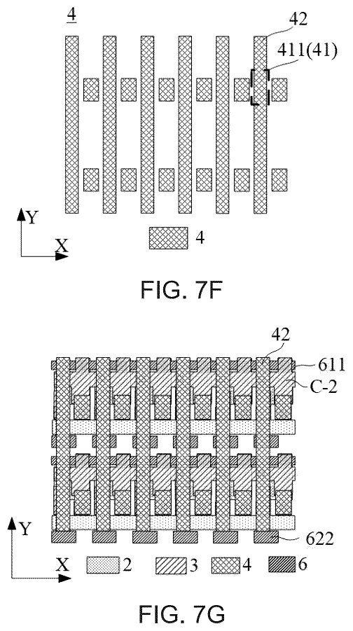

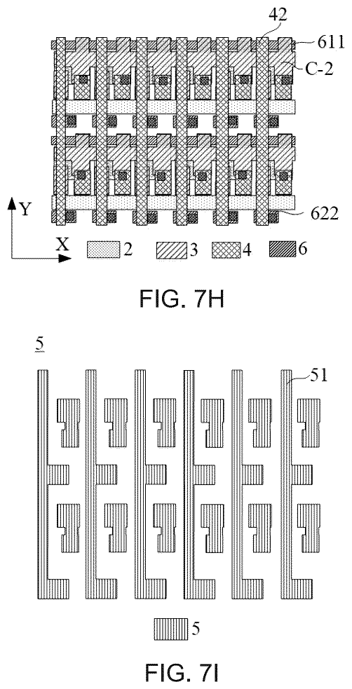

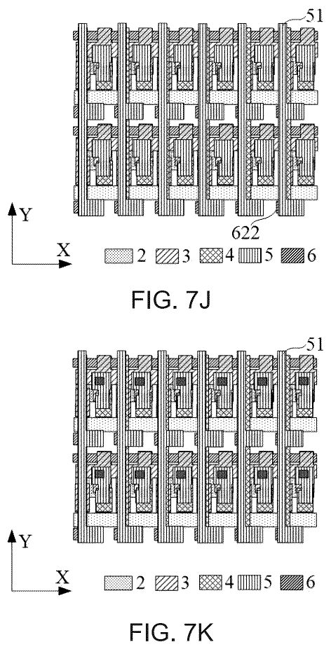

In some embodiments, as shown in FIGS. 9, and 10A, the plurality of pixel driving circuits P are arranged in multiple rows in the third direction Y and arranged in multiple columns in the second direction X. Any two adjacent rows of pixel driving circuits P are arranged in symmetry.

In this way, the design and fabrication difficulty of the patterns of the plurality of pixel driving circuits P may be simplified, which is conducive to fully utilizing the space of the display substrate 100.

In some embodiments, as shown in FIG. 6B, the second active pattern 62 further includes a third connection portion 622 arranged opposite to the second connection portion 621, and the third connection portion 622 is electrically connected to the data line 51.

The manner of the electrical connection between the third connection portion 622 and the data line 51 may vary.

For example, as shown in FIG. 6B, the second gate conductive layer 3 further includes second connection patterns 32. The second connection patterns 32 and the first connection patterns 31 are spaced apart. An end of the second connection pattern 32 is electrically connected to the data line 51, and another end of the second connection pattern 32 is electrically connected to the third connection portion 622, thereby realizing the electrical connection between the third connection portion 622 and the data line 51.

Alternatively, the third connection portion 622 may be directly electrically connected to the data line 51 through a via hole.

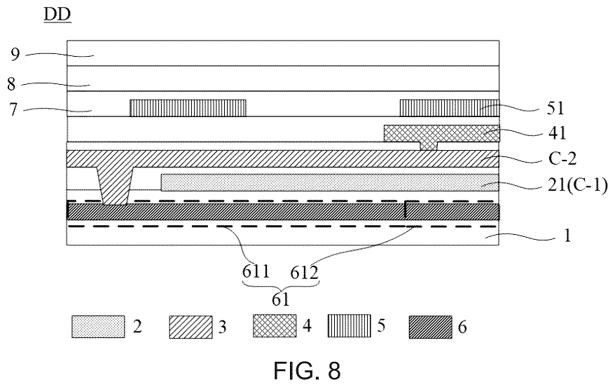

In some examples, referring to FIGS. 9 and 11, in a 2N-th row of pixel driving circuits P₁ and a (2N+1)-th row of pixel driving circuits P₂, third connection portions 622 of two pixel driving circuits located in the same column are of an integrated structure, N being a positive integer.

In this way, two adjacent pixel driving circuits in the same column may be designed to be more compact, thereby reducing the space occupied by the 2N-th row of pixel driving circuits P₁ and the (2N+1)-th row of pixel driving circuits P₂ in the display substrate 100, which is conducive to realizing the high PPI display of the display substrate 100.

In some embodiments, referring to FIGS. 10A, 10B and 11, in the 2N-th row of pixel driving circuits P₁ and the (2N+1)-th row of pixel driving circuits P₂, third connection portions 622 of two pixel driving circuits located in the same column are electrically connected to the data line 51 through the same via hole K₁.

In this way, it may be possible to reduce the number of via holes, simplify the structure of the display substrate 100, simplify the manufacturing process of the display substrate 100, and simplify the design difficulty of a mask for forming the above via hole K₁.

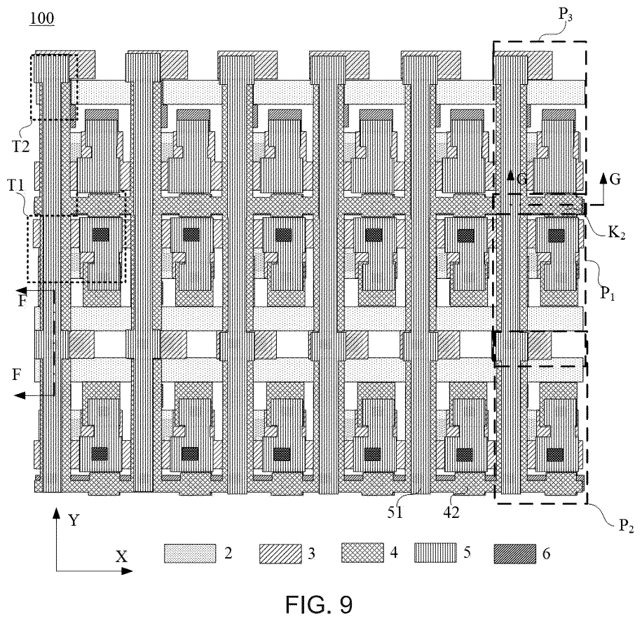

In some embodiments, as shown in FIG. 12, in a 2N-th row of pixel driving circuits P₁ and an (2N−1)-th row of pixel driving circuits P₃, first connection portions 611 of two pixel driving circuits located in the same column are of an integrated structure, N being a positive integer.

In this way, two adjacent pixel driving circuits in the same column may be designed to be more compact, thereby reducing the space occupied by the 2N-th row of pixel driving circuits P₁ and the (2N−1)-th row of pixel driving circuits P₃ in the display substrate 100, which is conducive to realizing the high PPI display of the display substrate 100.

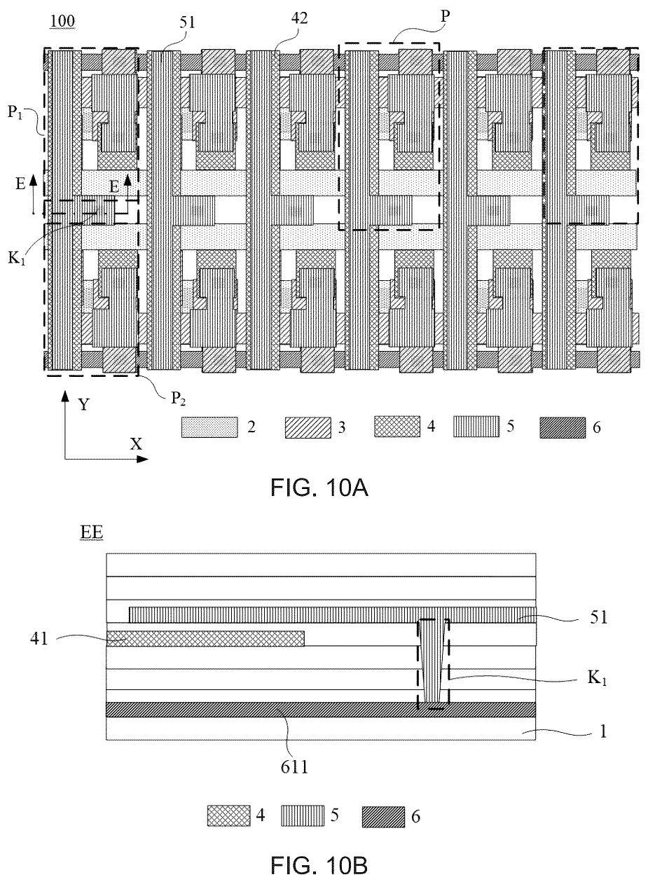

In some embodiments, as shown in FIG. 13, the first source-drain conductive layer further includes a plurality of first power supply voltage signal lines 42 extending in the second direction X, a first power supply voltage signal line 42 electrically connected to conductive patterns 41 of the 2N-th row of pixel driving circuits P₁ and a first power supply voltage signal line 42 electrically connected to conductive patterns 41 of the (2N−1)-th row of pixel driving circuits P₃ are of an integrated structure, N being a positive integer.

In this way, the number of first power supply voltage signal lines 42 in the display substrate may be reduced, so that two adjacent pixel driving circuits in the same column may be designed to be more compact, which may reduce the space occupied by the 2N-th row of pixel driving circuits P₁ and the (2N−1)-th row of pixel driving circuits P₃ in the display substrate 100, which is conducive to realizing the high PPI display of the display substrate 100.

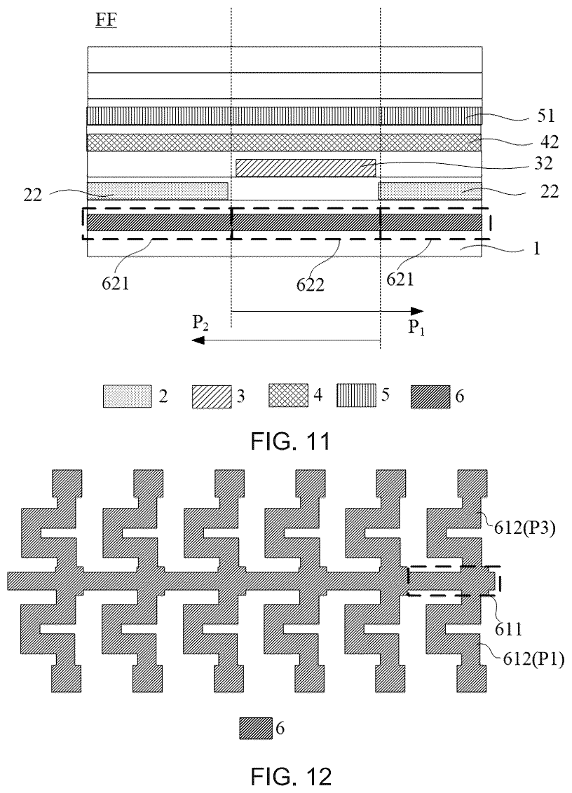

In some embodiments, referring to FIGS. 9 and 14, in the 2N-th row of pixel driving circuits P₁ and the (2N−1)-th row of pixel driving circuits P₃, first connection portions 611 of two pixel driving circuits located in the same column are electrically connected to the first power supply voltage signal lines 42 through the same via hole K2.

In this way, it may be possible to reduce the number of via holes, simplify the structure of the display substrate 100, simplify the manufacturing process of the display substrate 100, and simplify the design difficulty of a mask for forming the above via hole K₂.

In some examples, as shown in FIG. 6B, the display substrate 100 further includes a planarization layer 7, a pixel definition layer 8, and an encapsulation layer 9 that are located on the second source-drain conductive layer 5.

For example, the planarization layer 7 is formed by curing an organic material with good fluidity, so that a planar surface of the planarization layer 7 may be formed, which facilitates the arrangement of the first electrodes of the light-emitting devices L.

For example, the pixel definition layer 8 is made of an insulating material, and the pixel definition layer 8 is used for defining light-emitting regions of the light-emitting devices L. By providing the pixel definition layer 8, the light-emitting devices L may have different light-emitting regions. Therefore, the light-emitting devices L may display different graphics.

For example, the encapsulation layer 9 is used for protecting a region covered by the encapsulation layer 9.

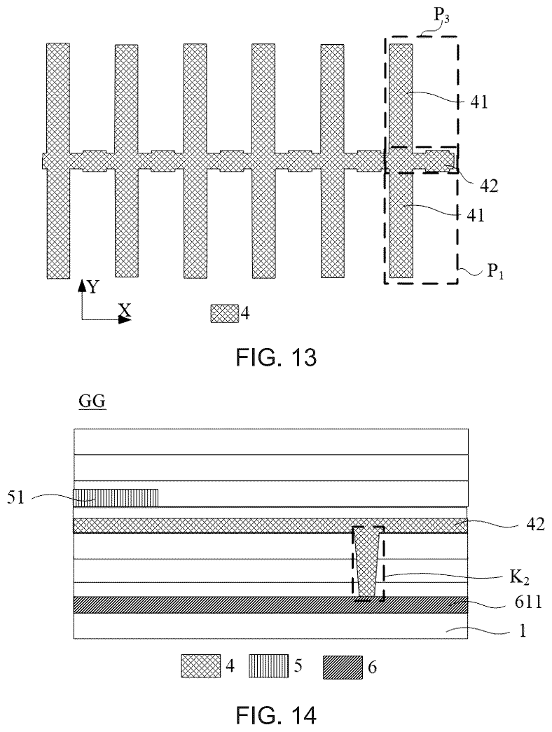

In another aspect, some embodiments of the present disclosure further provide a method for manufacturing a display substrate 100. The display substrate 100 includes a plurality of pixel driving circuits P. The pixel driving circuit P includes at least a first transistor T1 and a storage capacitor C. As shown in FIG. 15, the method includes S100 to S400.

In S100, a substrate 1 is provided.

In S200, a first gate conductive layer 2 is formed on the substrate 1. As shown in FIG. 6B, the first transistor T1 includes a first gate pattern 21 located in the first gate conductive layer 2, and the first gate pattern 21 is also used as a first electrode plate C-1 of the storage capacitor C.

In S300, a second gate conductive layer 3 is formed on the first gate conductive layer. As shown in FIG. 6B, the storage capacitor C includes a second electrode plate C-2 located in the second gate conductive layer 3. Orthographic projections, on the substrate 1, the second electrode plate C-2 and the first electrode plate C-1 partially overlap.

In S400, a first source-drain conductive layer 4 is formed on the second gate conductive layer 3. As shown in FIG. 6B, the first source-drain conductive layer 4 includes conductive patterns 41, and the conductive pattern 41 is electrically connected to the second electrode plate C-2.

The conductive pattern 41 includes a sub-portion 411, and orthographic projections, on the substrate 1, the sub-portion 411 and the first electrode plate C-1 overlap.

In the display substrate 100 formed by the above method, the conductive pattern 41 is electrically connected to the second electrode plate C-2, which is equivalent to increasing the area of the second electrode plate C-2 of the storage capacitor C. Moreover, since the orthographic projections, on the substrate 1, of the sub-portion 411 of the conductive pattern 41 and the first electrode plate C-1 overlap, the overlapping area of the sub-portion 411 and the first electrode plate C-1 may be increased in addition to the original overlapping area of the first electrode plate C-1 and the second electrode plate C-2, which increases the capacitance value of the storage capacitor C. Thus, it may be possible to enhance the stability of the data signal stored in the storage capacitor C in the pixel driving circuit P.

In some embodiments, the pixel driving circuit P further includes a second transistor T2. Before forming the first gate conductive layer 2, the method further includes: forming a semiconductor layer 6 on the substrate; and forming a first gate insulating film 10 on the semiconductor layer 6.

For example, the first gate insulating film 10 is used to protect the semiconductor layer 6. A material of the gate insulating layer may be, for example, one of silicon oxide, silicon nitride, and silicon oxynitride.

In the above-mentioned another implementation, as shown in FIG. 5, the second electrode plate 2′ is directly connected to the first active pattern 4′ located in the active layer through a via hole. That is, after forming the first electrode plate 1′ and an insulating layer on the first electrode plate 1′, the insulating layer is etched to form the via hole for exposing a part of the first active pattern 4′; then, the via hole is cleaned with a cleaning solution to remove residues in the via hole to reduce the contact resistance between the second electrode plate 2′ and the first active pattern 4′. The cleaning solution is a buffered oxide etching solution, which is a mixture of hydrofluoric acid and water (where the concentration of hydrofluoric acid is 49%), or a mixture of ammonium fluoride and water.

However, the cleaning solution may also corrode the insulating layer on the first electrode plate 1′, causing the insulating layer to become thinner and crack, which may lead to a risk of short circuit between the second electrode plate 2′ and the first electrode plate 1′.

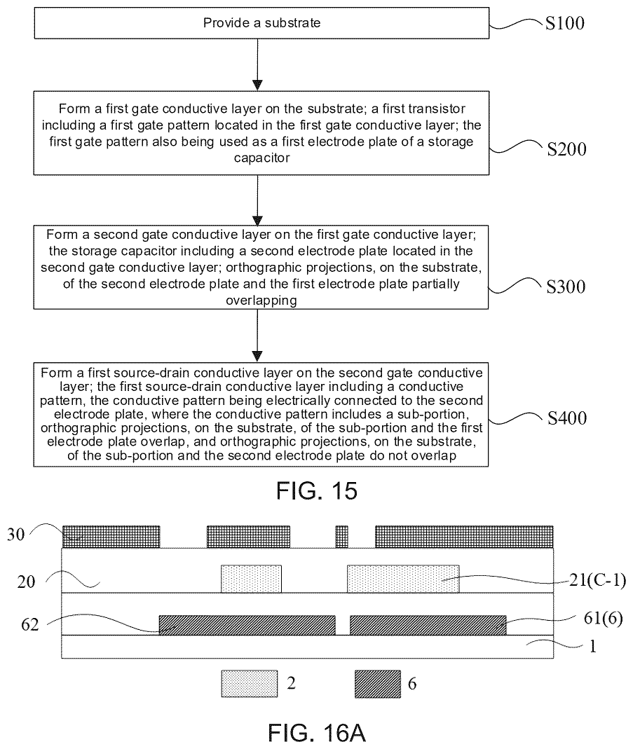

In some embodiments provided in the present disclosure, after forming the first gate conductive layer 2 and before forming the second gate conductive layer 3, the method further includes: as shown in FIG. 16A, forming a second gate insulating film 20 on the first gate conductive layer 2; as shown in FIG. 16A, forming a mask pattern (also named as a first mask pattern) 30 on the second gate insulating film 20; as shown in FIG. 16B, etching a to-be-formed display substrate through the first mask pattern 30 to form first via hole(s) K1 that penetrate the first gate insulating film 10 and the second gate insulating film 20 and expose parts of the semiconductor layer 6, and second via hole(s) K2 that penetrate the second gate insulating film 20 and expose parts of the first gate conductive layer 2; cleaning the to-be-formed display substrate using a cleaning solution; and as shown in FIG. 16C, removing the first mask pattern 30.

For example, positions where the first via holes K1 and the second via holes K2 are located are used to form the above-mentioned first connection patterns 31.

In this way, during the process of etching the to-be-formed display substrate through the first mask pattern 30, the first mask pattern 30 may protect a region covered by the first mask pattern 30, and may prevent the cleaning solution from corroding the region covered by the first mask pattern 30, thereby preventing the second gate insulating film 20 from becoming thinner, and reducing the risk of short circuit between the first electrode plate C-1 and the subsequently formed second electrode plate C-2.

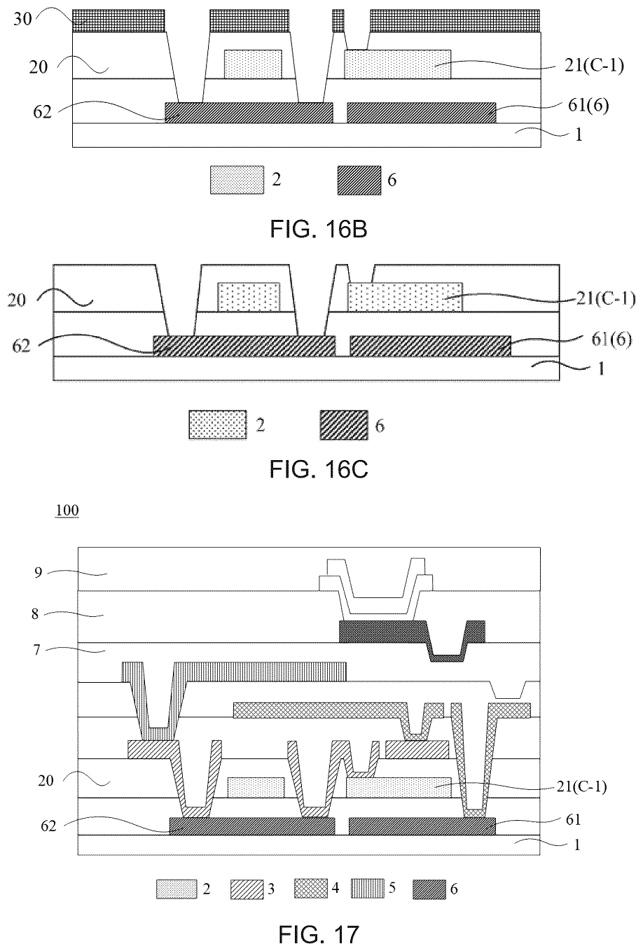

In some examples, after S400, the method further includes: as shown in FIG. 17, forming a second source-drain conductive layer 5 on the first source-drain conductive layer 4; forming a planarization layer 7 on the second source-drain conductive layer 5; forming a pixel definition layer 8 on the planarization layer 7; and forming an encapsulation layer 9 on the pixel definition layer 8.

The foregoing descriptions are merely specific implementation manners of the present disclosure, but the protection scope of the present disclosure is not limited thereto, any changes or replacements that a person skilled in the art could conceive of within the technical scope of the present disclosure shall be included in the protection scope of the present disclosure. Therefore, the protection scope of the present disclosure shall be subject to the protection scope of the claims.

1. A display substrate, comprising a plurality of pixel driving circuits, each pixel driving circuit of the plurality of pixel driving circuits including at least a first transistor and a storage capacitor;
the display substrate further comprising:
a substrate;
a first gate conductive layer located on the substrate, wherein the first transistor includes a first gate pattern located in the first gate conductive layer, and the first gate pattern is also used as a first electrode plate of the storage capacitor;
a second gate conductive layer located on the first gate conductive layer, wherein the storage capacitor includes a second electrode plate located in the second gate conductive layer; and orthographic projections, on the substrate, of the second electrode plate and the first electrode plate partially overlap; and
a first source-drain conductive layer located on the second gate conductive layer, wherein the first source-drain conductive layer includes at least one conductive pattern, and a conductive pattern of the at least one conductive pattern is electrically connected to the second electrode plate;
wherein the conductive pattern includes a sub-portion; and orthographic projections, on the substrate, of the sub-portion and the first electrode plate overlap.

2. The display substrate according to claim 1, wherein the second gate conductive layer includes a first connection pattern that is spaced apart from the second electrode plate, and the first connection pattern is electrically connected to the first electrode plate;
orthographic projections, on the substrate, of the first connection pattern and the sub-portion overlap.

3. The display substrate according to claim 1, wherein the pixel driving circuit further includes a second transistor, and the second transistor includes a second gate pattern located in the first gate conductive layer;
an orthographic projection of the second gate pattern on the substrate is located within an orthographic projection of the conductive pattern on the substrate.

4. The display substrate according to claim 3, further comprising:
a second source-drain conductive layer located on the first source-drain conductive layer, wherein the second source-drain conductive layer includes data lines extending in a first direction, the first direction being parallel to a plane where the substrate is located;
the orthographic projection of the second gate pattern on the substrate is located within the orthographic projection of the conductive pattern on the substrate, and is located within an orthographic projection of a data line of the data lines on the substrate.

5. The display substrate according to claim 1, wherein the pixel driving circuit further includes a second transistor;
the display substrate further comprises a semiconductor layer located between the substrate and the first gate conductive layer;
the first transistor includes a first active pattern located in the semiconductor layer; the first active pattern includes a first connection portion and a first channel region sequentially arranged in a first direction, the first direction being parallel to a plane where the substrate is located; orthographic projections, on the substrate, of the first channel region, the first electrode plate and the second electrode plate partially overlap; the first connection portion is electrically connected to the conductive pattern;
the second transistor includes a second active pattern located in the semiconductor layer, the second active pattern includes a second connection portion, and the second connection portion is electrically connected to the first electrode plate.

6. The display substrate according to claim 5, wherein the at least one conductive pattern includes a plurality of conductive patterns, and the plurality of conductive patterns are arranged in a plurality of rows and a plurality of columns; each row of conductive patterns is arranged in a second direction, and each column of conductive patterns is arranged in a third direction, the second direction and the third direction intersecting and both being parallel to the plane where the substrate is located; the first source-drain conductive layer further includes a plurality of first power supply voltage signal lines extending in the second direction;
a first power supply voltage signal line is electrically connected to conductive patterns in a same row.

7. The display substrate according to claim 6, wherein the first power supply voltage signal line and the conductive patterns electrically connected to the first power supply voltage signal line are of an integrated structure.

8. The display substrate according to claim 6, wherein orthographic projections, on the substrate, of the first connection portion and the second electrode plate do not overlap;
the first connection portion is electrically connected to the first power supply voltage signal line, and is electrically connected to the conductive pattern through the first power supply voltage signal line.

9. The display substrate according to claim 5, wherein the at least one conductive pattern includes a plurality of conductive patterns, and the plurality of conductive patterns are arranged in a plurality of rows and a plurality of columns; each row of conductive patterns is arranged in a second direction, and each column of conductive patterns is arranged in a third direction, the second direction and the third direction intersecting and both being parallel to the plane where the substrate is located;
wherein conductive patterns located in a same column are electrically connected to constitute a first power supply voltage signal line.

10. The display substrate according to claim 9, wherein the conductive patterns located in the same column are of an integrated structure.

11. The display substrate according to claim 9, wherein orthographic projections, on the substrate, of the first connection portion and the second electrode plate overlaps;
the first connection portion is electrically connected to the second electrode plate, and is electrically connected to the conductive pattern through the second electrode plate.

12. The display substrate according to claim 9, wherein a plurality of second electrode plates of storage capacitors in the plurality of pixel driving circuits are arranged in a plurality of rows and a plurality of columns, each row of second electrode plates is arranged in the second direction, and each column of second electrode plates is arranged in the third direction; and second electrode plates located in a same row are electrically connected.

13. The display substrate according to claim 5, wherein a plurality of first active patterns of first transistors in the plurality of pixel driving circuits are arranged in a plurality of rows and a plurality of columns, each row of first active patterns is arranged in a second direction, and each column of first active patterns is arranged in a third direction, the second direction and the third direction intersecting and both being parallel to the plane where the substrate is located;
wherein first connection portions of first active patterns located in a same row are connected.

14. The display substrate according to claim 5, wherein the plurality of pixel driving circuits are arranged in a plurality of rows and a plurality of columns, each row of pixel driving circuits is arranged in a second direction, and each column of pixel driving circuits is arranged in a third direction, the second direction and the third direction intersecting and both being parallel to the plane where the substrate is located;
any two adjacent rows of pixel driving circuits are arranged in symmetry.

15. The display substrate according to claim 14, further comprising a second source-drain conductive layer located on the first source-drain conductive layer, wherein the second source-drain conductive layer includes data lines extending in the first direction;
the second active pattern further includes a third connection portion, the third connection portion and the second connection portion are respectively located at two ends of the second active pattern, and the third connection portion is electrically connected to a data line of the data lines;
in a 2N-th row of pixel driving circuits and a (2N+1)-th row of pixel driving circuits, third connection portions of two pixel driving circuits located in a same column are of an integrated structure, N being a positive integer.

16. The display substrate according to claim 14, wherein in a 2N-th row of pixel driving circuits and a (2N−1)-th row of pixel driving circuits, first connection portions of two pixel driving circuits located in a same column are of an integrated structure, N being a positive integer.

17. The display substrate according to claim 14, wherein the first source-drain conductive layer further includes a plurality of first power supply voltage signal lines extending in the second direction, and a first power supply voltage signal line electrically connected to conductive patterns of a 2N-th row of pixel driving circuits and a first power supply voltage signal line electrically connected to conductive patterns of a (2N−1)-th row of pixel driving circuits are of an integrated structure, N being a positive integer.

18. A display device, comprising the display substrate according to claim 1.

19. A method for manufacturing a display substrate, wherein the display substrate includes a plurality of pixel driving circuits, and a pixel driving circuit includes at least a first transistor and a storage capacitor;
the method comprising:
providing a substrate; and
forming a first gate conductive layer on the substrate, wherein the first transistor includes a first gate pattern located in the first gate conductive layer, and the first gate pattern is also used as a first electrode plate of the storage capacitor;
forming a second gate conductive layer on the first gate conductive layer, wherein the storage capacitor includes a second electrode plate located in the second gate conductive layer, and orthographic projections, on the substrate, of the second electrode plate and the first electrode plate partially overlap; and
forming a first source-drain conductive layer on the second gate conductive layer, wherein the first source-drain conductive layer includes a conductive pattern, and the conductive pattern is electrically connected to the second electrode plate; the conductive pattern includes a sub-portion; orthographic projections, on the substrate, of the sub-portion and the first electrode plate overlap; and orthographic projections, on the substrate, of the sub-portion and the second electrode plate do not overlap.

20. The method according to claim 19, wherein the pixel driving circuit further includes a second transistor;
before forming the first gate conductive layer, the method further comprises:
forming a semiconductor layer on the substrate; and
forming a first gate insulating film on the semiconductor layer; and
after forming the first gate conductive layer and before forming the second gate conductive layer, the method further comprises:
forming a second gate insulating film on the first gate conductive layer;
forming a mask pattern on the second gate insulating film;
etching a to-be-formed display substrate through the mask pattern, so as to form a first via hole that penetrates the first gate insulating film and the second gate insulating film and exposes a part of the semiconductor layer and a second via hole that penetrates the second gate insulating film and exposes a part of the first gate conductive layer;
cleaning the to-be-formed display substrate using a cleaning solution; and
removing the mask pattern.
